(19) United States
(12) Patent Application Publication
(10) Pub. No.: US 2005/0142876 A1
(43) Pub. Date: Jun. 30, 2005

(54) Maskless lateral epitaxial overgrowth of aluminum nitride and high aluminum composition aluminum gallium nitride

(76) Inventors: Thomas Matthew Katona, Columbia, SC (US); Stacia Keller, Santa Barbara, CA (US); Pablo Cantu Alejandro, Raleigh, NC (US)

Correspondence Address: GATES & COOPER LLP;HOWARD HUGHES CENTER, 6701 CENTER DRIVE WEST, SUITE 1050, LOS ANGELES, CA, 90045, US

(21) Appl. No.: 10/973,332

(22) Filed: Oct. 25, 2004

Related U.S. Application Data
(60) Provisional application No. 60/514,082, filed on Oct. 24, 2003.

(51) Int. Cl. H01L 29/15; H01L 31/0312; H01L 21/44

(52) U.S. Cl. 438/688

(57) ABSTRACT

A method of maskless lateral epitaxial overgrowth (LEO) of aluminum nitride (AlN) and high aluminum composition aluminum gallium nitride (AlGaN) layers by crystal growth techniques, such as metalorganic chemical vapor deposition (MOCVD), Hydride Vapor Phase Epitaxy (HVPE), other vapor phase transport techniques such as sublimation, and Molecular Beam Epitaxy (MBE). The process etches periodic patterns into a suitable material, such AlN or high aluminum composition AlGaN base layers heteroepitaxially grown on a substrate or a substrate itself. A lateral epitaxial overgrowth is performed of the AlN or high aluminum composition AlGaN layers on the suitable material. Lateral epitaxial overgrowth of the AlN or high aluminum composition AlGaN layers may be enhanced by using low V/III ratios and fast growth rates. The process reduces the threading dislocation density (TDD) in high Al containing nitrides by several orders of magnitude.

### CROSS-REFERENCE TO RELATED APPLICATIONS

This application claims the benefit under 35 U.S.C. § 19(e) of the following co-pending and commonly-assigned U.S. patent application:
U.S. Provisional Patent Application Ser. No. 60/514,082, filed on Oct. 24, 2003, by Thomas M. Katona, Stacia Keller, and Pablo Cantu Alejandro, entitled “MASKLESS LATERAL EPITAXIAL OVERGROWTH OF ALUMINUM NITRIDE AND HIGH ALUMINUM COMPOSITION ALUMINUM GALLIUM NITRIDE,” attorneys' docket no. 30794.109-US-P1;
which application is incorporated by reference herein.

### BACKGROUND OF THE INVENTION

1. Field of the Invention

This invention relates to semiconductor devices, and more particularly, to a maskless lateral epitaxial overgrowth (LEO) of aluminum nitride (AlN) and high aluminum composition aluminum gallium nitride (AlGaN).

2. Description of the Related Art

Gallium nitride (GaN) absorbs light in the ultraviolet (UV) range, while AlN is transparent to UV light. Aluminum (Al) based III-V nitride materials offer the possibility of shorter wavelength devices for various applications such as higher storage capacity DVDs, bio and chemical sensors (agents absorb in UV and reemit at another wavelength), and water purification (UV can be used to kill bacteria). However, it is difficult to provide lateral overgrowth of AlN and high aluminum composition AlGaN.

Lateral overgrowth has been applied to GaN for use in such devices as blue light emitting diodes, laser diodes, and electronic devices, but has previously been thought to be limited to GaN and low x AlₓGa₍₁₋ₓ₎N. Although dislocation reduction through lateral overgrowth of GaN works well, devices that require AlGaN can not be grown on these GaN base layers without causing cracking from the tensile stress in the film. Vertical light emitting devices with wavelengths shorter than ˜365 nm also suffer from self absorption of the generated light by GaN base layers which reduces the optical output power. The development of low dislocation AlN or high aluminum composition AlGaN base layers not only enhances device characteristics through dislocation reduction, but provides a UV transparent epitaxial base layer for vertical light emitting devices. AlN and high aluminum composition AlGaN base layers grown heteroepitaxially on traditional substrates have suffered from a large number of edge type dislocations, even though progress has been made in reducing the number of screw type dislocations.

What is needed, then, are improved methods of lateral overgrowth of AlN and high aluminum composition AlGaN.

### SUMMARY OF THE INVENTION

To overcome the limitations in the prior art described above, and to overcome other limitations that will become apparent upon reading and understanding the present specification, the present invention discloses a method of maskless LEO of AlN and high aluminum composition AlGaN layers by crystal growth techniques, such as metalorganic chemical vapor deposition (MOCVD), Hydride Vapor Phase Epitaxy (HVPE), other vapor phase transport techniques such as sublimation, and Molecular Beam Epitaxy (MBE). The process prepares a suitable material, such as heteroepitaxially grown AlN or high aluminum composition AlGaN base layers on a substrate or a substrate itself, by etching periodic patterns into the suitable material. The lateral epitaxial overgrowth is then performed to grow the AlN or high aluminum composition AlGaN layers on the prepared suitable material. Lateral epitaxial overgrowth of the AlN or high aluminum composition AlGaN layers may be enhanced by using low V/III ratios and fast growth rates. The process reduces the threading dislocation density (TDD) in high Al containing nitrides by several orders of magnitude.

### BRIEF DESCRIPTION OF THE DRAWINGS

Referring now to the drawings in which like reference numbers represent corresponding parts throughout:

FIGS. 1A, 1B, 2A and 2B illustrate process flows for preparing base layers or a substrate for lateral epitaxial overgrowth and a subsequent lateral epitaxial overgrowth process.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

The present invention describes the lateral growth of AlN or high aluminum composition AlGaN containing materials for threading dislocation reduction of these materials. This technique provides AlN or high aluminum composition base layers with a superior microstructure than is obtained through direct heteroepitaxy for the development of high performance nitride based devices.

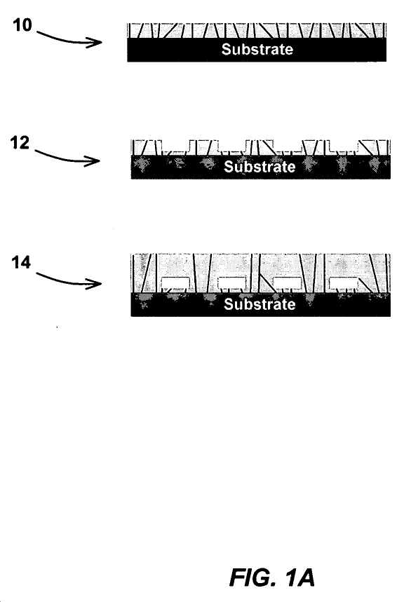

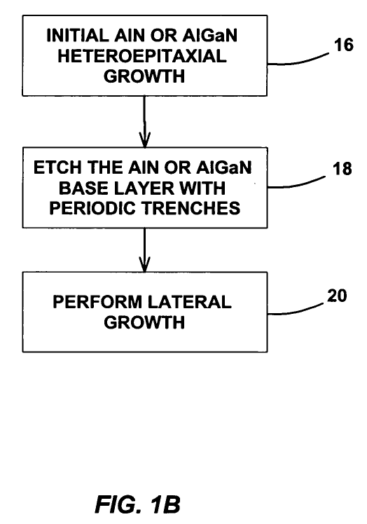

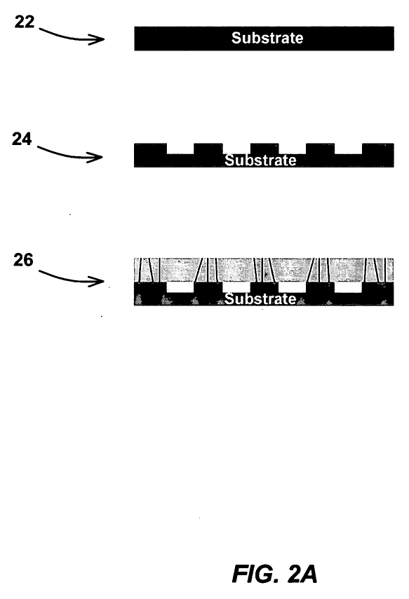

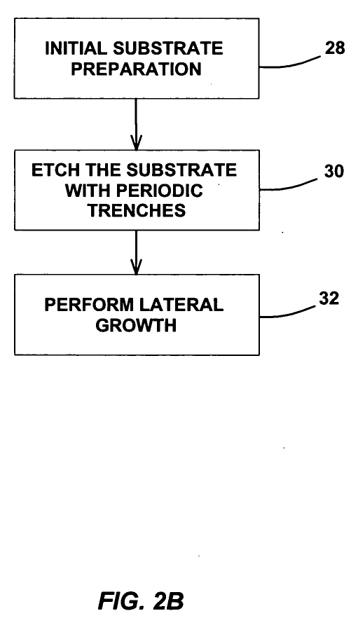

FIGS. 1A, 1B, 2A and 2B illustrate process flows for preparing a suitable material, such as base layers on a substrate or a substrate alone, for lateral growth and the subsequent lateral growth process on the suitable material. Specifically, the figures illustrate base layer and substrate preparation, and subsequent lateral overgrowth required for maskless LEO of AlN and high aluminum containing AlGaN layers.

FIGS. 1A and 1B together comprise a first embodiment, which describes a process performed on an AlN or AlGaN base layer, while FIGS. 2A and 2B together comprise a second embodiment, which describes a process performed directly on a substrate.

In FIGS. 1A and 1B, there is an AlN or AlGaN base layer heteroepitaxial grown on a substrate, represented by 10 in FIG. 1A and 16 in FIG. 1B. Next, periodic patterns or trenches are etched into the AlN or AlGaN base layer, represented by 12 in FIG. 1A and 18 in FIG. 1B. Finally, a lateral epitaxial overgrowth of the AlN or high aluminum composition AlGaN layers is performed on the base layer, represented by 14 in FIG. 1A and 20 in FIG. 1B, to achieve a planar film with low dislocation density areas. The lateral epitaxial overgrowth may be performed using crystal growth techniques, such as MOCVD, HVPE, other vapor phase transport techniques such as sublimation, and MBE. The lateral epitaxial overgrowth of the AlN or high aluminum composition AlGaN layers may be enhanced using low V/III ratios (e.g., ratios less than 1000) and fast growth rates (e.g., rates greater than 2 Å per second).

In FIGS. 2A and 2B, there is an initial preparation of a substrate, represented by 22 in FIG. 2A and 28 in FIG. 2B. Next, periodic patterns or trenches are etched into the substrate, represented by 24 in FIG. 2A and 30 in FIG. 2B. Finally, a lateral epitaxial overgrowth of the AlN or high aluminum composition AlGaN layers is performed on the substrate, represented by 26 in FIG. 2A and 30 in FIG. 2B, to achieve a planar film with low dislocation density areas. The lateral epitaxial overgrowth may be performed using crystal growth techniques, such as MOCVD, HVPE, other vapor phase transport techniques such as sublimation, and MBE. The lateral epitaxial overgrowth of the AlN or high aluminum composition AlGaN layers may be enhanced using low V/III ratios (e.g., ratios less than 1000) and fast growth rates (e.g., rates greater than 2 Å per second).

In both embodiments, the periodic patterns or trenches may be comprised of stripes, circles, hexagons, or other patterns. Moreover, the depth of the etched patterns allows for material from neighboring mesas to coalesce before material in the etched patterns grows up to the laterally growing material.

After the completion of the process, the user is left with a planar wafer with areas of low threading dislocation density material. Depending on the percentage of the wafer that has a low dislocation density, the process can be repeated by etching into the high dislocation density areas and performing a second regrowth, resulting in the entire wafer being free of dislocations.

Previously, the factors preventing the extension of this process from GaN to high aluminum composition AlGaN and AlN were a combination of the slow lateral growth rate of aluminum containing compounds, and the lack of selectivity between a mask and unmasked region for aluminum containing compounds. Aluminum containing compounds stick to surfaces much more readily than GaN does. These two issues are addressed through a combination of growth conditions and base layer preparation. The slow lateral growth rate is addressed by using much lower V/III ratios than are typically used for growth of III-V nitrides, e.g., 1-1000 as compared to several thousand. The lateral growth was also enhanced through the use of high growth rates, e.g., ˜3 μm/hr. Although this condition is not required, it greatly increases the overgrowth geometries that can be achieved by allowing for faster overgrowth of the trench regions.

The lack of selectivity for aluminum containing compounds was addressed by removing the mask material completely and overgrowing a trench instead of a mask material. It is possible that a mask material may work in combination with these growth conditions to enhance the lateral growth rate. Possible mask materials include, but are not limited to, SiO₂, Si₃N₄, Ti, Pt, Ge, TiO₂, and C.

### Conclusion

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

1. A method of maskless lateral epitaxial overgrowth (LEO) of aluminum nitride (AlN) layers, comprising:
preparing a suitable material by etching periodic patterns into the suitable material; and
performing a lateral epitaxial overgrowth of an AlN layer on the prepared suitable material.

2. The method of claim 1, wherein the suitable material comprises an AlN base layer heteroepitaxially grown on a substrate.

3. The method of claim 1, wherein the suitable material comprises a substrate.

4. The method of claim 1, wherein the periodic patterns are comprised of stripes, circles, hexagons, or other patterns.

5. The method of claim 1, wherein the lateral epitaxial overgrowth of the AlN layer is enhanced by using low V/III ratios.

6. The method of claim 5, wherein the low V/III ratios are ratios less than 1000.

7. The method of claim 1, wherein the lateral epitaxial overgrowth of the AlN layer is enhanced by using fast growth rates.

8. The method of claim 1, wherein a depth of the etched patterns allows for material from neighboring mesas to coalesce before material in the etched patterns grows up to the laterally growing material.

9. The method of claim 1, wherein the lateral epitaxial overgrowth is performed using crystal growth techniques, such as metalorganic chemical vapor deposition (MOCVD), Hydride Vapor Phase Epitaxy (HVPE), other vapor phase transport techniques such as sublimation, or Molecular Beam Epitaxy (MBE).

10. One or more AlN layers grown using the method of claim 1.

11. One or more devices fabricated using the method of claim 1.

12. A method of maskless lateral epitaxial overgrowth (LEO) of high aluminum composition aluminum gallium nitride (AlGaN) layers, comprising:
preparing a suitable material by etching periodic patterns into the suitable material; and
performing a lateral epitaxial overgrowth of a high aluminum composition AlGaN layer on the prepared suitable material.

13. The method of claim 12, wherein the suitable material comprises an AlGaN base layer heteroepitaxially grown on a substrate.

14. The method of claim 12, wherein the suitable material comprises a substrate.

15. The method of claim 12, wherein the periodic patterns are comprised of stripes, circles, hexagons, or other patterns.

16. The method of claim 12, wherein the lateral epitaxial overgrowth of the high aluminum composition AlGaN layer is enhanced by using low V/III ratios.

17. The method of claim 16, wherein the low V/III ratios are ratios less than 1000.

18. The method of claim 12, wherein lateral epitaxial overgrowth of the high aluminum composition AlGaN layer is enhanced by using fast growth rates.

19. The method of claim 10, wherein a depth of the etched patterns allows for material from neighboring mesas to coalesce before material in the etched patterns grows up to the laterally growing material.

20. The method of claim 12, wherein the lateral epitaxial overgrowth is performed using crystal growth techniques, such as metalorganic chemical vapor deposition (MOCVD), Hydride Vapor Phase Epitaxy (HVPE), other vapor phase transport techniques such as sublimation, or Molecular Beam Epitaxy (MBE).

21. One or more high aluminum composition AlGaN layers grown using the method of claim 12.

22. One or more devices fabricated using the method of claim 12.
